(19) United States
(12) Patent Application Publication
(10) Pub. No.: US 2010/0243037 A1
(43) Pub. Date: Sep. 30, 2010

(54) ANTITHEFT PROTECTION FOR PHOTOVOLTAIC MODULE

(75) Inventors: VALERY AUROUSSEAU, ST CLAIR DE LA TOUR (FR); FRANTZ ALLANDRIEU, SAINT MAURICE DE GOURDANS (FR); PASCAL BARGUIRDJIAN, SAINT MALO (FR)

Correspondence Address: CANTOR COLBURN, LLP, 20 Church Street, 22nd Floor, Hartford, CT, 06103, US

(73) Assignees: PHOTOWATT INTERNATIONAL, BOURGOIN JALLIEU (FR); TECKNISOLAR-SENI, COURBEVOIE (FR)

(21) Appl. No.: 12/731,588

(22) Filed: Mar. 25, 2010

(30) Foreign Application Priority Data
Mar. 27, 2009 (FR) 09/01490

(51) Int. Cl. H01L 31/00

(52) U.S. Cl. 136/254; 136/256

(57) ABSTRACT

A photovoltaic solar module inclueing at least one photovoltaic cell and terminals for connection to an electrical network, means of deactivating the module arranged to establish a shunt at the connection terminals of the module and disable the module, a body that moves in a housing cavity according to at least one degree of freedom between a first position in which the body does not interact with the deactivation means and a second position in which the body interacts with the deactivation means so as to establish a shunt at the connection terminals of the module, and a means of blocking the body in the second position.

### TECHNICAL FIELD

The disclosure relates to the field of antitheft protection for photovoltaic modules, and more particularly to a photovoltaic module equipped with a disabling device intended to discourage thefts.

### BACKGROUND

The theft of photovoltaic modules, also called solar modules, is a misdemeanor that must be stopped as quickly as possible because it represents a hindrance to their economic development. In practice, this type of module is often installed on a support in the ground or in places that can easily be accessed and/or that are isolated. Thus, it becomes easy to steal a photovoltaic module, since it only has to be disconnected from the network to which it is connected and then removed from its support.

Currently, there are various electronic and mechanical alarm systems added to a solar module to make it possible to know in real time of the theft and the degradation of a solar module on an isolated site.

On this subject, the document DE 20 2007 008512 U1 can be cited, which proposes fixing devices intended to receive alarm sensors in order to signal any attempt to remove photovoltaic modules from their support.

One of these devices is incorporated in the solar module, cannot be seen by the naked eye and is provided with an electronic or mechanical alarm system which is tripped or which cuts the electrical production of the solar module when a screw that acts on a magnet with flexible blade contact is manually unscrewed.

Another of these devices consists in neutralizing the electricity production function via a digital processing operation driven by the electronics, this device being costly and complex to implement.

However, these proposed systems have hitherto been easy to circumvent by manual or electrical intervention such as shunting, extraction, unscrewing or transformation.

These devices therefore only have a discouraging function that does not in any way prevent the photovoltaic module from being remounted operationally other than on its original support, which does not discourage criminal deeds. Furthermore, these security means added to the solar module increase the cost of the solar panels.

This type of discouragement is therefore effective only if the photovoltaic modules are under constant surveillance and if the reaction times and other response times to these modules after the alarms have been tripped are short.

The aim of the present invention is to propose a solution to these drawbacks.

### BRIEF SUMMARY

To this end, the subject of the present invention is a photovoltaic solar module comprising at least one photovoltaic cell and terminals for connection to an electrical network, characterized in that it also comprises means of deactivating the module arranged to establish a shunt at the connection terminals of the module and disable the module, a body that moves in a housing cavity according to at least one degree of freedom between a first position in which the body does not interact with the deactivation means and a second position in which the body interacts with the deactivation means so as to establish a shunt at the connection terminals of the module, and a means of blocking the body in the second position.

This arrangement makes it possible to neutralize the production of electricity supplied by a daytime solar module in the event of unauthorized handling and dismantling during the day or night on an isolated site.

The transition of the body to the second position is blocking, the means of blocking in the second position does not allow the module to be switched back to an operational state, which renders the module unusable and does more to prevent thefts.

Thus, the assembly includes the cavity, the deactivation means, the moving body and the blocking means constitutes a disabling device intended to discourage thefts.

According to one embodiment, the cavity is included in laminated layers of the solar module.

This arrangement makes it possible to hide the cavity and thus prevent access thereto. The very small cavity is ideally inlaid on the same support as the electrical circuit of the solar cells and/or embedded in the same resin as the latter so that extraction of the cavity will cause irreversible damage to the photovoltaic laminate and the solar cells, proving that the panel has been stolen and vandalized.

According to another embodiment, the deactivation means comprise two conductive tabs.

These conductive tabs make it possible to reduce the bulk of the deactivation means while helping to lower its cost.

According to one embodiment, the body exhibits magnetic properties.

The magnetic properties of the body make it possible to help keep it in the second position.

According to the same embodiment, the magnetic body is a ball.

The ball shape enables the body to be displaced by rolling inside the cavity in the direction of the gravity that is exerted on it and the orientation of the module.

Advantageously, the means of blocking the body in the second position is a magnet.

The magnet combined with the magnetic properties of the body makes it possible to keep the latter in the second position regardless of the orientation of the module.

According to one embodiment, the means of blocking the body helps to bring the body to the second position.

This arrangement increases the tripping sensitivity of the interaction between the body and the deactivation means and therefore the disabling of the module. It is therefore not enough, to keep the module operational, to transport the module in one and the same orientation, which is already very difficult to do. It is also possible to envisage a module support that would necessarily lead to a disorientation of the module when it is extracted from this same support.

According to one embodiment, means for clamping the moving body in the first position are arranged in the cavity.

These means make it possible to prevent the body from reaching the second position when transporting the module to its place of installation and when installing it.

According to the same embodiment, the means for clamping the moving body in the first position comprise a tab passing through the cavity.

This tab allows an easy and inexpensive implementation of a means retaining the body in its first clamping position for transportation and installation.

Advantageously, the displacement of the means for clamping the body in the first position is irreversible.

This arrangement does not make it possible to neutralize the displacement of the body by a simple repositioning of the means of clamping the body in its first position without damaging or vandalizing the clamping insert passage.

In any case, the invention will be clearly understood from the following description, given with reference to the appended diagrammatic drawings, representing by way of nonlimiting example one embodiment of a solar module according to the invention.

### BRIEF DESCRIPTION OF THE DRAWINGS

FIG. 1 is a schematic overview of a module according to the invention comprising a disabling device.

FIG. 2 is a cross-sectional diagram of the disabling device before the module is enabled.

FIG. 3 is a cross-sectional diagram of the disabling device when the module is enabled.

FIG. 4 is a cross-sectional diagram of the disabling device when the latter has been engaged.

### DETAILED DESCRIPTION

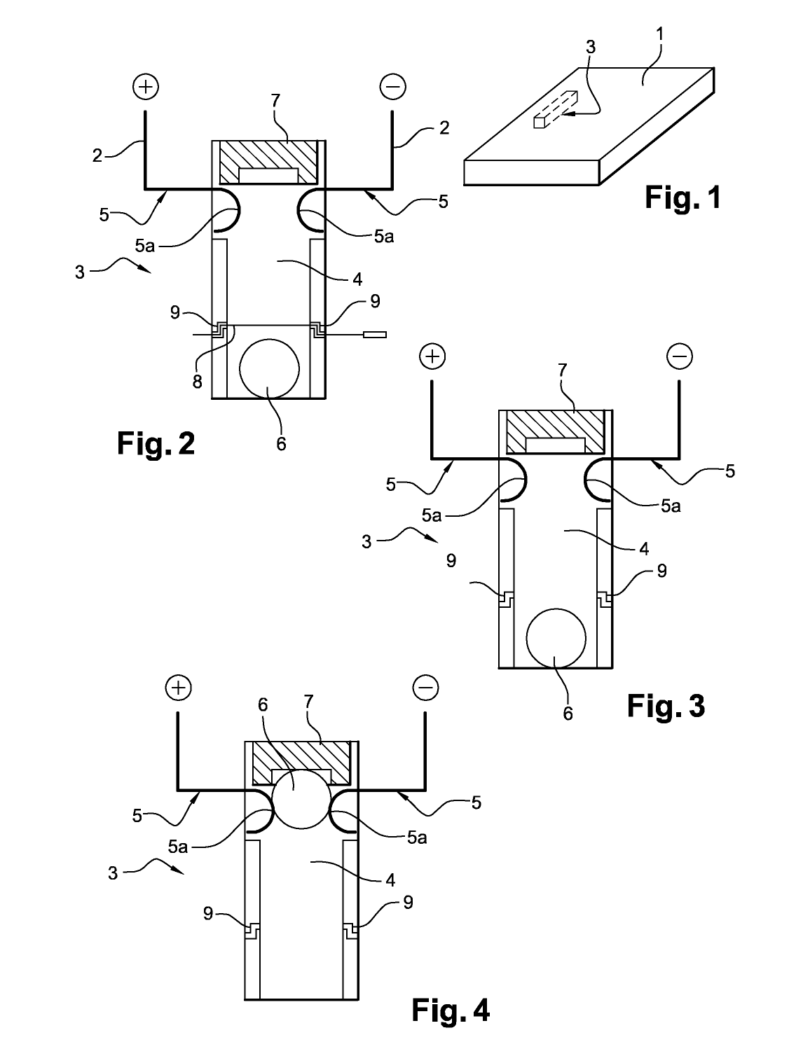

According to the embodiment represented in FIGS. 1 to 4, a photovoltaic module 1 comprises means of connecting to the electricity network 2 comprising two output terminals: a plus terminal and a minus terminal that are separate, and a cavity 4 arranged in the thickness of the laminates of the photovoltaic module 1 in order to make it invisible.

According to variants, the cavity can be formed in any other part of the module that prevents direct access to the device without vandalism.

The cavity 4 has a cylindrical shape. Electrical deactivation means 5 represented by two tabs 5 each deriving from one of the plus and minus output terminals of the module 1 project transversely inside the cylindrical cavity in a predetermined position.

These tabs 5 are arranged symmetrically opposite one another inside the cylindrical cavity 4. Their ends 5a projecting inside the cylindrical cavity 4 are curved in order to give their profile a semi-circular shape. This semi-circular shape gives them an elasticity dependent on their bending radius.

A conductive ball, notably made of steel 6, is positioned inside the cylindrical cavity 4. This steel has good electrical and magnetic properties and is inexpensive, which makes it a good material for implementing the device.

A plastic clamping tab 8 is positioned transversely through bent passages 9 arranged either side of the wall of the cylindrical cavity 4 so as to prevent the steel ball 6 from being displaced freely inside the cavity 4 during transportation or even installation of the module on its support or frame (not represented).

Finally, a magnet 7 is positioned in the cylindrical cavity 4 on the side opposite to the steel ball 6 relative to the conductive tabs 5. The steel ball 6 and the magnet 7 are therefore placed at rest on the two bases of the cylinder formed by the cavity 4.

The assembly including the cavity 4, the conductive tabs 5, the steel ball 6, the magnet 7, the clamping tab 8 and its passage bends 9 form the device 3.

Upon first installation of the photovoltaic module 1, the installer will place the solar module on a frame, a concrete cap, a roof, etc. Then the installer determines the correct orientation of the photovoltaic module 1 relative to the sun. This orientation varies according to the technology employed for the electricity production and the region. According to these parameters, it will be necessary to incline the module 1 by an angle ranging from 10° to 80° to the south/southwest in order to receive a maximum of sunlight but it can also be oriented it toward the east, the north and/or placed slightly flat, that is to say fixed to the horizontal.

The device 3 on the solar module 1 is positioned horizontally and/or vertically in order to avoid cutting the electricity production of the solar module 1 as a result of vibrations caused by the resonance of the engine or the passing of a running vehicle or boat.

This orientation should enable the steel ball 6 to remain positioned in the first position without it coming into contact with the plastic clamping tab 8, without which the module would immediately be disabled by the device 3 upon the releasing of the plastic clamping tab 8. It should be noted that the device 3 can be fixed equally to the back, the front or even the side of the photovoltaic module 1.

Once correctly oriented and fixed to its support, the installer then releases the plastic clamping tab 8 using the ring 8a positioned on one of its ends.

The bent passages 9 prevent the installer from reengaging the plastic clamping tab 8. The function of these bent passages 9 is therefore to solidly retain the tab 8 during transportation and installation and prevent the reintroduction of a tab 8 when the module 1 is enabled.

In this configuration, the device 3 is operational and the photovoltaic module 1 is enabled, in other words it will produce electricity when it sees the light of day. The photovoltaic module 1 is then protected by the device 3.

Upon an attempted theft or any other illegal act which causes a displacement of the module 1, the orientation and/or the inclination of the module 1 and therefore of the device 3 are modified.

The steel ball 6 is then moved in the cylindrical cavity 4 under the action of gravity together with the orientation of the module 1. This movement will irretrievably cause the steel ball 6 to be moved in the field of attraction of the magnet 7 which, together with gravity, will attract it to the second position.

The steel ball 6 will then come into contact with the two conductive tabs 5, which will cause the two conductive tabs 5 to be set to the same potential and therefore the network connection terminals 2 to be short circuited, which will cause the electricity production of the photovoltaic module 1 to be stopped.

Under the action of the magnet 7, the steel ball 6 will also be engaged between the two elastic ends 5a of the two conductive tabs 5 by pushing them back laterally toward the walls of the cylindrical cavity 4 until it reaches the magnet 7.

The steel ball 6 is then in its second position and is retained there by the action of the magnet 7.

In this configuration, the device 3 is activated and the photovoltaic module 1 is disabled.

The invention also makes it possible to deactivate the device 3. In practice, if the stolen, and consequently disabled solar module is retrieved by the owner, a portable mobile device can be used to reenable the photovoltaic module 1, that is to say, to reposition the steel ball 6 in its first position, and do so without dismantling, without external electrical manipulation and without transformation.

This mobile device subjects the steel ball 6 to an opposing magnetic flux making it possible to automatically return the conductive ball 6 to its first position by simply stroking the photovoltaic module in the place where the device 3 is positioned.

The device cannot be reenabled by manipulating an undefined magnet in the vicinity of the device 3.

A portion of the front panel of the photovoltaic module 1 can be provided with a note indicating that it is protected by mechanical vibration and oscillation against unauthorized displacement or removal.

The invention makes it possible to protect a photovoltaic module 1 at low cost and discourage theft thereof with a movement-based mechanical and automatic technology.

The device 3 encapsulated in the photovoltaic module 1 will have the same lifetime as the photovoltaic module 1 and will not require servicing.

To return the solar panel to an energy producing state, the device 3 has to be accessed to be neutralized. This act of vandalism will provide the physical proof of a transformation of the photovoltaic module 1 following a theft or displacement.

It goes without saying that the invention is not limited to the preferred embodiment described hereinabove by way of nonlimiting example; on the contrary, it encompasses all the variants. In particular, the plastic clamping tabs 8 can be replaced by a rod, a cleat, a key or any other system that can provide the same clamping function.

1. A photovoltaic solar module comprising:
at least one photovoltaic cell and terminals for connection to an electrical network,
means of deactivating the module arranged to establish a shunt at the connection terminals of the module and disable the module,
a body that moves in a housing cavity according to at least one degree of freedom between a first position in which the body does not interact with the deactivation means and a second position in which the body interacts with the deactivation means so as to establish a shunt at the connection terminals of the module, and
means of blocking the body in the second position.

2. The photovoltaic solar module as claimed in claim 1, wherein the cavity is included in laminated layers of the solar module or any other placement requiring a partial destruction of the solar module.

3. The photovoltaic solar module as claimed in claim 1, wherein the deactivation means comprise two conductive tabs.

4. The photovoltaic solar module as claimed in claim 1, wherein the body exhibits magnetic properties.

5. The photovoltaic solar module as claimed in claim 4, wherein the magnetic body is a ball.

6. The photovoltaic solar module as claimed in claim 4, wherein the means of blocking the body in the second position is a magnet.

7. The photovoltaic solar module as claimed in claim 1, wherein the means of blocking the body helps to bring the body to the second position.

8. The photovoltaic solar module as claimed in claim 1, further comprising means for clamping the moving body in the first position, arranged in the cavity.

9. The photovoltaic solar module as claimed in claim 8, wherein the means for clamping the moving body in the first position comprise a tab passing through the cavity.

10. The photovoltaic solar module as claimed in claim 8, wherein the displacement of the means for clamping the body in the first position is irreversible.
